(19) United States
(12) Patent Application Publication
(10) Pub. No.: US 2007/0062280 A1
(43) Pub. Date: Mar. 22, 2007

(54) Method for manufacturing a mass-spring system

(76) Inventor: Henrik Jakobsen, Horten (NO)

Correspondence Address: EDELL, SHAPIRO & FINNAN, LLC, 1901 RESEARCH BOULEVARD, SUITE 400, ROCKVILLE, MD, 20850, US

(21) Appl. No.: 11/515,914

(22) Filed: Sep. 6, 2006

(30) Foreign Application Priority Data
Sep. 6, 2005 (EP) 05255430.0

(51) Int. Cl. H01L 21/306; G01P 15/097; G01P 15/18; G01P 9/04

(52) U.S. Cl. 73/504.04; 73/504.12; 73/514.38; 73/510; 438/694

(57) ABSTRACT

A method for manufacturing a micromechanical mass-spring system that includes a mass and an asymmetric spring is provided. A silicon substrate is provided, and the silicon substrate is etched to define a section upon which the asymmetric spring is to be formed. A surface layer is formed on the surface of the substrate. Etching is then performed to form the asymmetric spring from the surface layer, and further etching releases the mass and spring from the substrate. A device that includes a micromechanical mass-spring system manufactured according to the method is also provided.

### CROSS REFERENCE TO RELATED APPLICATIONS

This application claims priority under 35 U.S.C. §119 to Application No. EP 05255430.0 filed on Sep. 6, 2005, entitled “Method for Manufacturing a Mass-Spring System,” the entire contents of which are hereby incorporated by reference.

### FIELD OF THE INVENTION

The present invention relates to the manufacture of a micromechanical mass-spring system for use as an inertial device. The invention further relates to micromechanical mass-spring systems incorporating thin asymmetric springs and a method of manufacturing such systems, using bulk etching and bulk and/or surface micromachining techniques.

### BACKGROUND

Micro electromechanical systems (MEMS) are becoming increasingly important in the manufacture of inertial devices such as angular rate sensors and multiple axis accelerometers. Micromechanical structures such as asymmetric springs, diaphragms and mass-spring systems are increasingly used in such devices, where these structures are used to obtain in-plane movements of structures when applying out-of-plane forces. The manufacturing methods of these structures generally involve bulk micromachining techniques.

Known devices which use such methods are realized by using the full wafer thickness of (100) silicon to define, for example, an asymmetric spring along the (111) plane by etching from both sides of the wafer. This results in springs typically thicker than 30 microns and a large spread in thickness, and a resulting large chip size. These methods strongly limit the downscaling of the dimensions of such springs, thereby limiting improvements in chip size and manufacturing costs.

Further prior art methods for manufacturing the asymmetric springs have aimed to reduce chip size using a combination of etch-stop against pn-junction techniques to form the thickness of the springs, a shallow wet etch to form the asymmetric feature and dry etching to release the springs from the manufacturing substrate. Such methods can produce springs with a practical thickness in the range of 10 to 20 microns, and a reduced width of approximately 5 microns including an asymmetric cut.

Known devices which employ such methods include devices for measuring force components using monocrystalline materials, such as 2-axis and 3-axis accelerometers and devices for measuring angular velocity and angular rate.

As mentioned above, limitations currently exist in the manufacturing methods of micromechanical structures such as asymmetric springs, and there is a need within the related industry to produce thinner structures in order to reduce the chip size of micromechanical inertial devices, in a cost-effective manner.

### SUMMARY

The present invention seeks to overcome the aforementioned problems, by providing an alternative manufacturing method which can be used to build mass-spring systems comprising asymmetric springs with a thickness down to sub-micron values and a corresponding width in the range of 1 micron or more, in an efficient and effective manufacturing method.

According to the present invention there is provided a method for manufacturing a micromechanical mass-spring system comprising a mass and an asymmetric spring, the method comprising: providing a silicon substrate; forming a mass on the substrate; etching the silicon substrate to define a section upon which the asymmetric spring is to be formed; forming a surface layer on the surface of the substrate; etching to form the asymmetric spring from the surface layer; and etching to release the mass and spring from the substrate.

Implementation of the present invention by using silicon process technology and by using photolithographic methods, thin-film deposition, doping and etching processes leads to the manufacture of much thinner asymmetric springs within mass-spring systems, thereby providing greater flexibility in the manufacture of inertial devices in which in-plane movements of micromechanical structures such as asymmetric springs occur when applying out-of-plane forces to the structures.

Mass-spring systems manufactured according to the present invention may also be incorporated in applications such as: 2- and 3-axis accelerometers, which may include capacitive detection; 1- and 2-axis angular rate sensors with electrostatic excitation and capacitive detection; a capacitive inertial measurement unit (IMU) comprising two chips, one of which has a gyro having up to two axes and an accelerometer having up to three axes, and the other of which has three signal conditioning means; and a complete single-chip IMU with a gyro having up to two axes and an accelerometer having up to three axes on the same chip.

A reduced chip size allows multiple inertial devices to be placed on the same chip, thereby facilitating the fitting of the chip to, for example, a vehicle.

Such devices may also be employed to design and manufacture different types of actuators that take advantage of obtaining in-plane movements when applying out of plane forces; for example parts for microvalves, micropumps, microgrippers, microhandling, microbiotics, etc.

### BRIEF DESCRIPTION OF THE DRAWINGS

Examples of the present invention will now be described with reference to the accompanying drawings, in which:

FIG. 1 shows manufacturing steps for thin asymmetric springs in single crystal silicon, using bulk etching and etch-stop against pn-junction techniques;

FIG. 2 shows an example of the manufacture of a mass-spring system according to an exemplary embodiment of the present invention in which some of the techniques of the method of FIG. 1 are employed;

FIG. 3 shows the manufacturing steps for creating out-of-plane springs in poly-silicon or other thin-film material;

FIG. 4 shows an example of the manufacture of a mass-spring system according to an exemplary embodiment of the present invention in which some of the techniques of the method of FIG. 2 are employed;

FIG. 5 shows a further example of the manufacture of a mass-spring system according to an exemplary embodiment of the present invention in which some of the techniques of the method of FIG. 2 are employed; and

FIG. 6 shows an example of a combined 3-axis accelerometer and 2-axis angular rate sensor, which incorporate mass-spring systems according to an exemplary embodiment of the present invention, on one chip.

### DETAILED DESCRIPTION

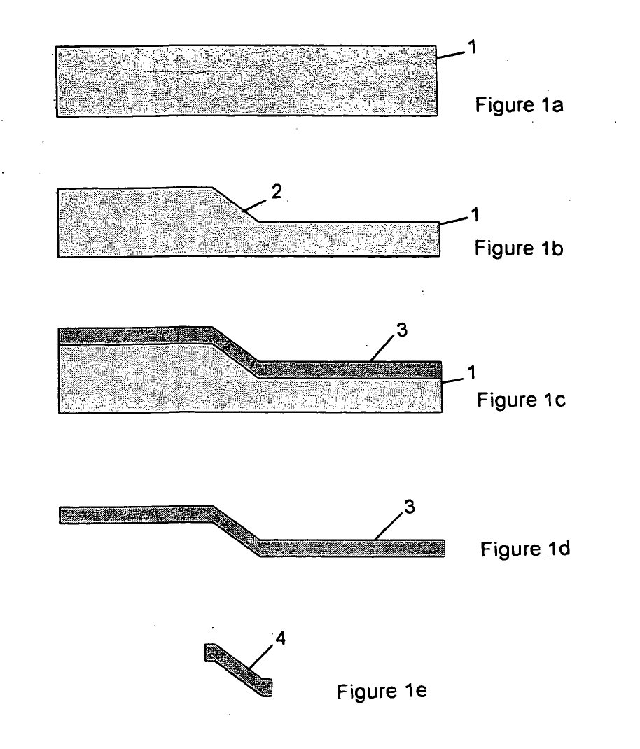

Referring to FIG. 1, the first step for manufacturing asymmetric springs in single crystal silicon according to one example of the invention is to provide a silicon substrate 1 on which the springs can be formed. In this example, the use of p-type silicon in the (100) plane is described; however, other silicon substrates can be used. A single crystal or silicon on insulator substrate may be employed.

Next, an anisotropic etching technique is used to etch the section of the silicon substrate 1 in the (111) plane, defining a wall 2 along this plane as illustrated in FIG. 1b.

FIG. 1c illustrates the formation of a doped surface layer 3 on the substrate 1. The n-type surface layer 3 is built by ion implantation and diffusion, and lies across the (111) wall 2 etched on the silicon substrate 1. The surface layer 3 is then detached from the substrate 1 (FIG. 1d) using an etch-stop against pn-junction technique in order to form of an asymmetric spring 4 with a desired asymmetric feature and thickness.

Finally, it is necessary to release the asymmetric spring 4 from the remainder of the surface layer 3 (FIG. 1e). This is done by standard photolithographic methods and dry-etching such as reactive ion etching (RIE), to create the length and width of the spring 4, which is shaped by the (111) silicon substrate wall 2 which acts as a support frame. This produces an asymmetric spring 4 with a thickness in the sub-micron to micron range, and a width in the range of one micron and above.

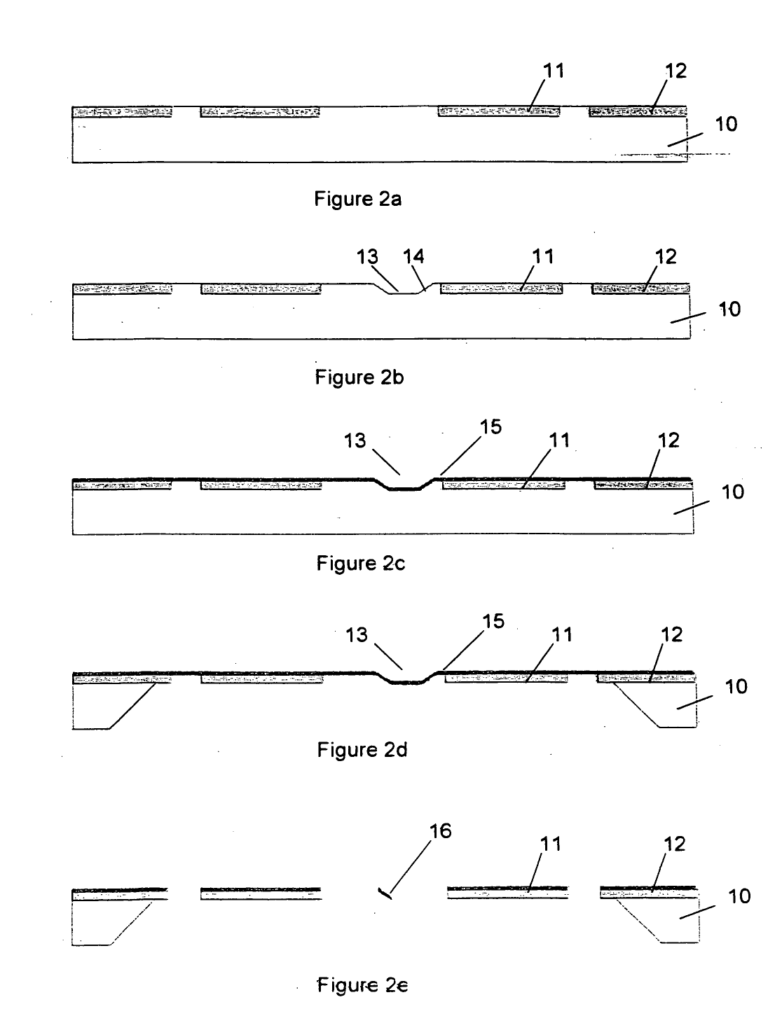

FIG. 2 shows a method of manufacturing a mass-spring system with a thin asymmetric spring according to the present invention. The method incorporates a method of manufacturing an asymmetric spring similar to that exemplified above in relation to FIG. 1. A substrate in the form of a p-type (100) silicon wafer 10 is doped with an n-type dopant to form masses 11 and a frame 12 of the mass-spring system, as shown in FIG. 2a. Anisotropic etching is performed (FIG. 2b) to form one or more grooves 13 with side walls 14 etched at a desired angle, for example in the (111) silicon plane. FIG. 2c illustrates the formation of a shallow doped surface layer 15 on the wafer 10. The n-type surface layer 15 is built by ion implantation and diffusion, and lies across the surfaces of the silicon wafer 10 including those of the groove 13 etched on the silicon wafer 10. The thickness of surface layer 15 determines the thickness of an asymmetric spring to be formed. FIG. 2d shows the result of electrochemical selective etching from a rear side of the wafer that stops against the pn-junction created. Finally, a complete mass-spring system is released from a front side of the wafer by, for example, dry etching (FIG. 2e) to complete the manufacture of the mass-spring system including an asymmetric spring 16.

The above method uses a combination of anisotropic wet etching, doping by ion implantation, etch-stop against pn-junction and dry etching techniques to create thin asymmetric springs in single-crystal silicon. The bulk micromachining techniques described can be combined with other processes to build complete sensor chips and other micromechanical inertial devices according to the present invention.

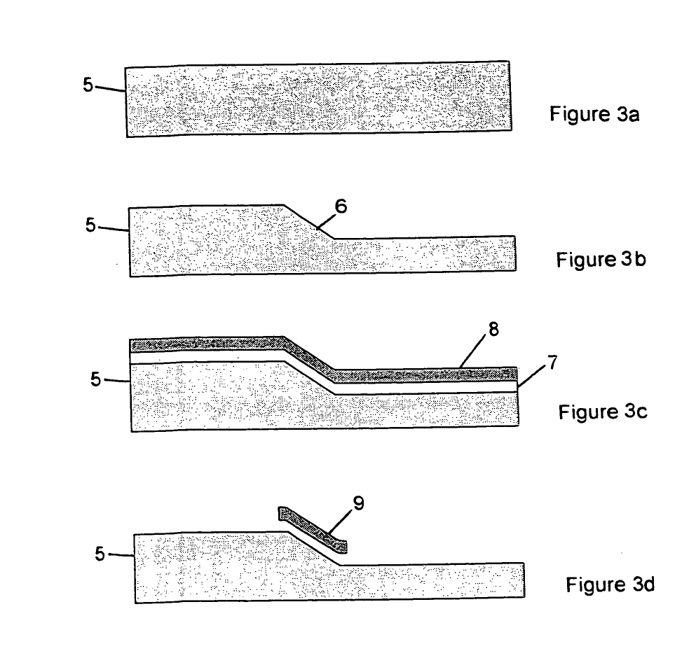

A further example of a manufacturing method of an asymmetric spring is illustrated in FIG. 3. This sequence of steps can be used to create out-of-plane asymmetric springs in poly-silicon or other deposited thin-film materials. Again, a p-type silicon substrate 5 in the (100) plane is provided on which to base the formation of the asymmetric springs. Anisotropic etching is performed to define a wall 6 along the (111) plane of the substrate 5 (FIG. 3b).

Next, a sacrificial layer 7 is created above the etched silicon substrate 5, as shown in FIG. 3c. The sacrificial layer 7 can be formed by thermal oxidation, or by depositing, for example, silicon dioxide onto the substrate 5. The sacrificial layer 7 can be composed of thermally grown silicon dioxide, deposited doped or undoped silicon dioxide, or other thin-film material that can be selectively removed and that can withstand the deposition temperature of the surface layer. A layer of elastic thin-film material, for example, poly-silicon 8, from which an asymmetric spring 9 will eventually be formed, is then deposited on the sacrificial layer 7 (FIG. 3c).

Finally, the poly-silicon layer 8 and sacrificial layer 7 are etched to form the asymmetric spring 9 and to release the micromechanical structure from the substrate 5, as shown in FIG. 3d.

The above steps therefore use a combination of bulk etching and surface-micromachining to create micromechanical structures such as thin asymmetric springs. This example of the present invention can be extended to build two-axis angular rate sensors and three-axis accelerometers as full single-chip structures.

The above methods are not limited to the realization of springs along the (111) plane on (100) substrate; out-of-plane springs can also be manufactured by etchings at different angles to the substrate surface plane. For example, different angles can be created on the substrate by using isotropic etching and deep, near 90° vertical etching. According to the present invention, micromechanical structures such as mass-spring systems for inertial devices can be made with a large variety of geometries, as defined by designing the patterns on photolithographic masks to be used in the photolithographic process that are incorporated in the manufacture of such asymmetric springs, as described below.

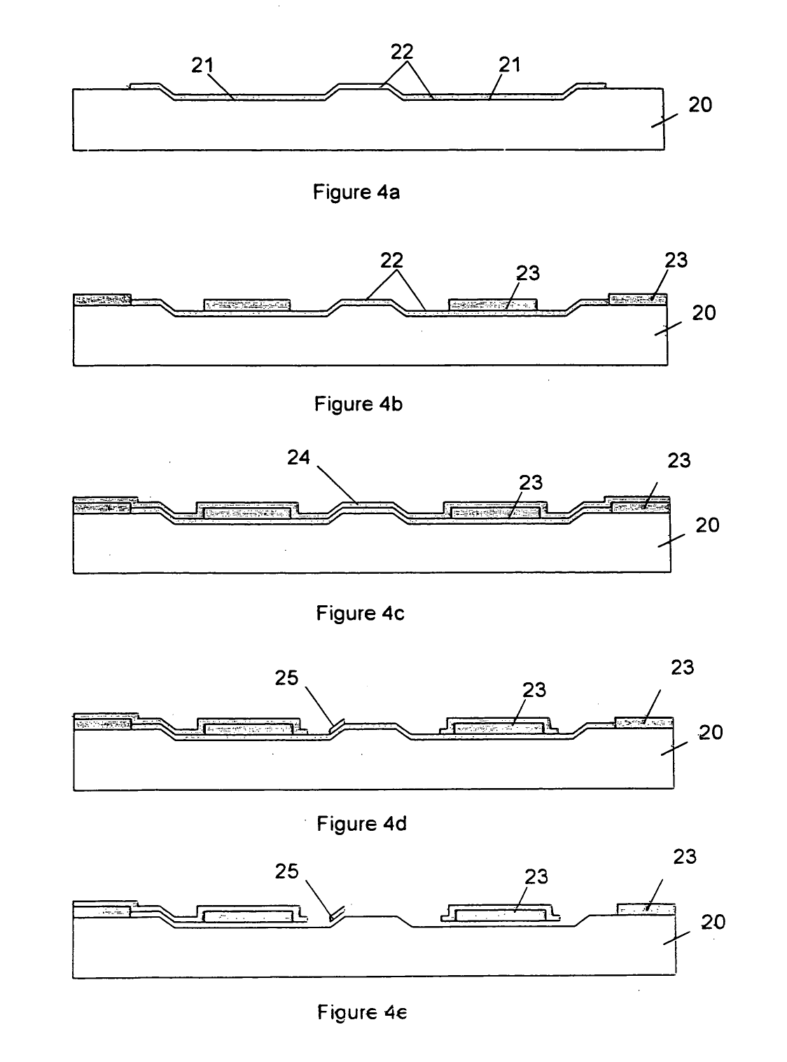

FIG. 4 shows a further method of manufacturing a mass-spring system with a thin asymmetric spring according to the present invention. The method incorporates a method of manufacturing an asymmetric spring similar to that exemplified above in relation to FIG. 3. One or more recesses 21 are etched in a silicon substrate 20 and a sacrificial layer 22 is deposited and etched therein as shown in FIG. 4a. Masses 23 are deposited on the sacrificial layer 22 and/or substrate 20 and are etched as required (FIG. 4b). A spring material layer 24 of, for example, poly-silicon, is then deposited on the sacrificial layer 22 and/or masses 23 (FIG. 4c), and this spring material layer 24 is then etched to form a spring 25 of the mass-spring system (FIG. 4d). Finally, the mass-spring system is released by etching of the sacrificial layer 22 (FIG. 4e).

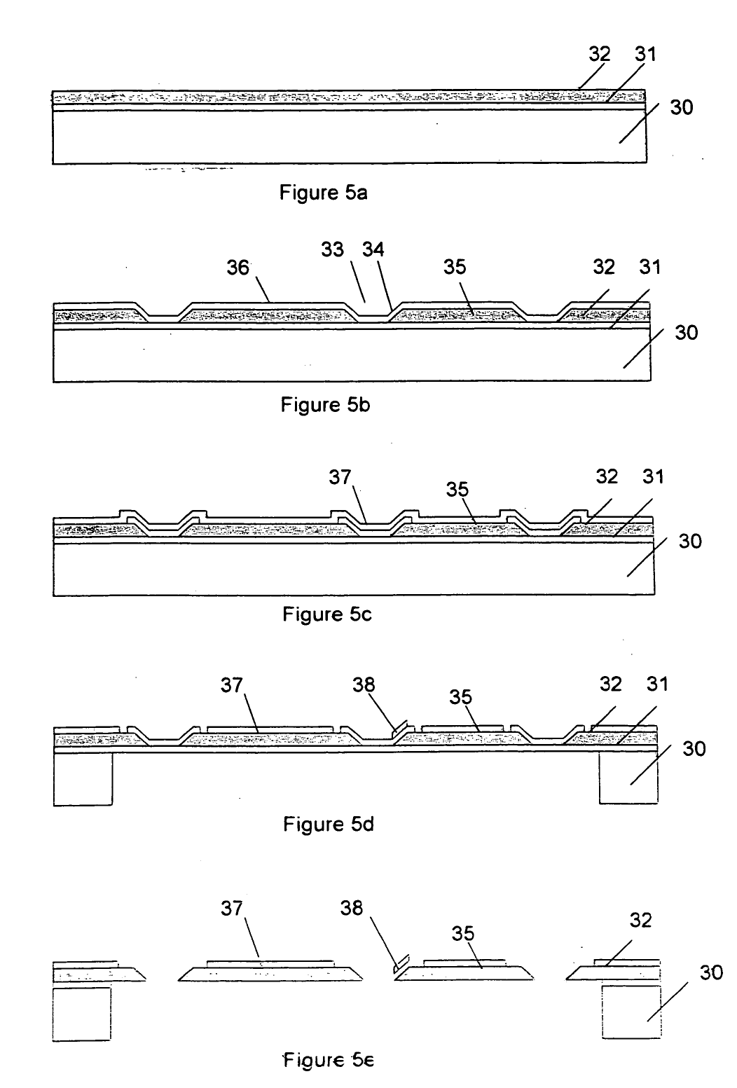

FIG. 5 shows a further method of manufacturing a mass-spring system with a thin asymmetric spring according to the present invention. This method also incorporates a method of manufacturing an asymmetric spring similar to that exemplified above in relation to FIG. 3. In this example, a silicon-on-insulator (SOI) wafer in the (100) plane comprising a silicon substrate 30, an insulating layer 31 and a p-type surface layer 32, is provided (FIG. 5a). One or more grooves 33 are provided by anisotropic etching of the substrate. The angles of the side walls 34 of the grooves can be in the (111) planes. The grooves define masses 35 in the substrate and provide areas on which springs are to be manufactured. A sacrificial layer 36 is then deposited over the substrate and masses (FIG. 5b) and etched (FIG. 5c). Thin-film spring material 37, such as poly-silicon, is then deposited on the sacrificial layer 36 (FIG. 5c) and this is then etched to define the geometry of a spring 37 (FIG. 5d). In this example, deep reactive ion etching is used to etch a rear side of the silicon wafer 30,31, such etching stopping against the insulating layer 32 (FIG. 5e). Finally, the insulating layer 32 is etched in an appropriate manner and the sacrificial layer 36 is removed to provide the mass-spring system comprising the thin asymmetric spring 38 (FIG. 5f).

As alternatives to performing anisotropic etching initially on the substrate, wet isotropic etching can be used, resulting in curved elements, or dry RIE etching can be used to define other angles between the surface plane of the substrate and masses and the surface plane of the spring elements.

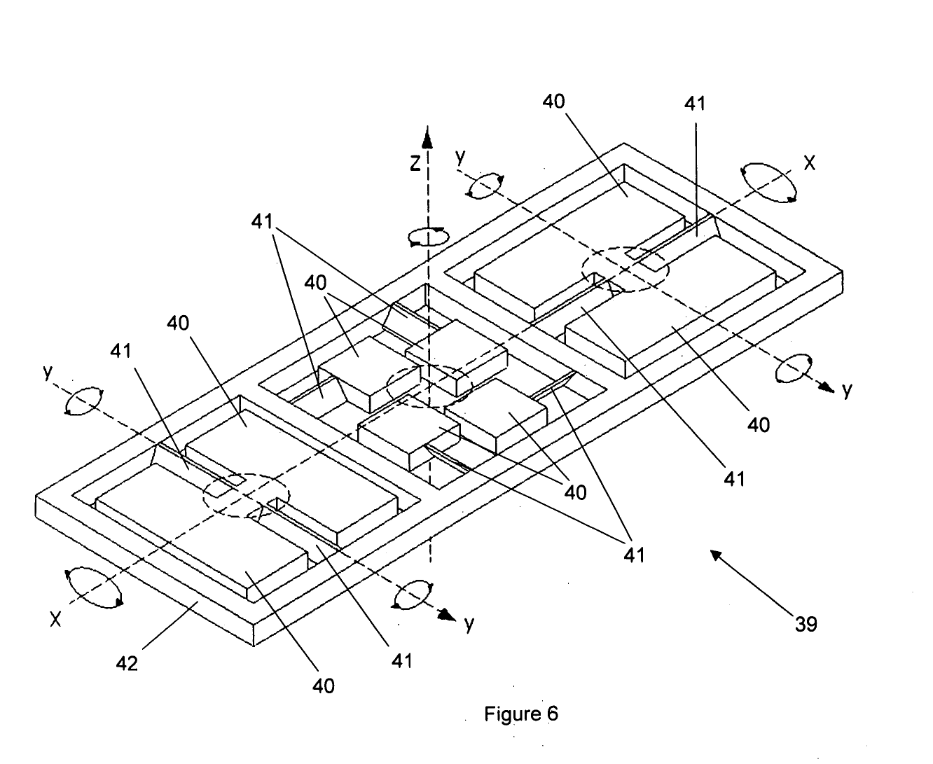

FIG. 6 shows an example of the implementation of the present invention to provide a combined 3-axis accelerometer and 2-axis angular rate sensor on a single inertial measurement unit (IMU) chip 39. In this example, masses 40 and springs 41 are provided on a single frame 42. Mass-spring systems according to the present invention can be provided in various combinations depending on the requirements of a user, and the integration of such systems on a single chip allows smaller, more reliable devices to be manufactured.

Alternative thin-film materials to poly-silicon may be used in the present invention, including strong elastic dielectrics such as silicon-nitride, other semi-conductor materials such as poly silicon germanium or silicon carbon, silicon-carbide, diamond-like-carbon and different metal films or insulating films which perform well as spring material, elastic thin-film materials such as Mo, W, Ti and Ni, and alloys including the shape-memory alloy TiNi.

The present invention therefore provides an efficient method of producing micromechanical mass-spring systems comprising asymmetric springs which are a great deal thinner than those obtained by previous known methods. This allows for smaller, more compact and less expensive micromechanical devices to be built with masses and asymmetric springs as required to obtain in-plane movements when applying out-of-plane forces, such as angular rate sensors and multiple axis accelerometers.

Having described exemplary embodiments of the present invention, it is believed that other modifications, variations and changes will be suggested to those skilled in the art in view of the teachings set forth herein. It is therefore to be understood that all such variations, modifications and changes are believed to fall within the scope of the present invention as defined by the appended claims. Although specific terms are employed herein, they are used in a generic and descriptive sense only and not for purposes of limitation.

What is claimed is:

1. A method for manufacturing a micromechanical mass-spring system comprising a mass and an asymmetric spring, the method comprising:
providing a silicon substrate;
forming a mass on the substrate;
etching the silicon substrate to define a section upon which the asymmetric spring is to be formed;
forming a surface layer on the surface of the substrate;
etching to form the asymmetric spring from the surface layer; and
etching to release the mass and spring from the substrate.

2. The method for manufacturing a micromechanical mass-spring system according to claim 1, wherein the silicon substrate is in the (100) plane.

3. The method for manufacturing a micromechanical mass-spring system according to claim 1, wherein the silicon substrate is anisotropically etched to define the (111) plane.

4. The method for manufacturing a micromechanical mass-spring system according to claim 1, further comprising:
doping the surface of the substrate via ion implantation or surface based deposition, such that opposite doping occurs, in order to form the surface layer.

5. The method for manufacturing a micromechanical mass-spring system according to claim 4, further comprising:
performing an etch-stop against pn-junction technique to form an asymmetrical shape of the asymmetric spring.

6. The method for manufacturing a micromechanical mass-spring system according to claim 1, further comprising:
dry-etching to release the asymmetric spring from the remainder of the surface layer.

7. The method for manufacturing a micromechanical mass-spring system according to claim 1, wherein the surface layer is formed of single-crystal silicon.

8. The method for manufacturing a micromechanical mass-spring system according to claim 1, further comprising:
forming a sacrificial layer between the silicon substrate and the surface layer via thermal oxidation.

9. The method for manufacturing a micromechanical mass-spring system according to claim 8, wherein the surface layer is formed of one of poly silicon, SiC, Ti, Ni or TiNi.

10. The method for manufacturing a micromechanical mass-spring system according to claim 1, further comprising:
forming a sacrificial layer via deposition of a material on the silicon substrate.

11. The method for manufacturing a micromechanical mass-spring system according to claim 10, wherein the surface layer is formed of one of poly silicon, SiC, Ti, Ni or TiNi.

12. A mass-spring system manufactured according to the method of claim 1.

13. A two-axis or three-axis accelerometer comprising a mass-spring system manufactured according to the method of claim 1.

14. An angular rate sensor comprising a mass-spring system manufactured according to the method of claim 1.

15. An inertial measurement unit (IMU) comprising one or more mass-spring systems manufactured according to the method of claim 1.

16. An inertial measurement unit (IMU) according to claim 15, the IMU comprising a chip, the chip further comprising a two-axis gyro and a three-axis accelerometer.

17. An inertial measurement unit (IMU) according to claim 16, the IMU further comprising a second chip having signal conditioning means.
